(19) United States
(12) Patent Application Publication
(10) Pub. No.: US 2026/0305093 A1
(43) Pub. Date: Oct. 1, 2026

(54) DISPLAY PANEL AND DISPLAY APPARATUS

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Ge NIU, Beijing (CN); Yi QU, Beijing (CN); Bo ZHANG, Beijing (CN); Yuanguo WANG, Beijing (CN); Xiangyi LI, Beijing (CN); Shuang LI, Beijing (CN); Hongbo MA, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 19/480,044

(22) PCT Filed: Feb. 8, 2025
(86) PCT No.: PCT/CN2025/076559

§ 371 Date: Oct. 30, 2025

(30) Foreign Application Priority Data
Mar. 20, 2024 (CN) 202410324205.9

(51) Int. Cl. H10K 59/131; H10K 59/124; H10K 102/00

(52) U.S. Cl. CPC H10K 59/131; H10K 59/124; H10K 2102/311

(57) ABSTRACT

A display panel includes a substrate and conductive layers. The conductive layers include: data lines, connection lines and fan-out lines. The data lines include first data lines and second data lines. At least one connection line crosses at least one data line, and is insulated from the at least one data line. A single fan-out line is connected to a single connection line or a single second data line. The fan-out lines include first-type fan-out lines. A first-type fan-out line includes an overlapping portion. In a thickness direction of the substrate, orthographic projections, on the substrate, of overlapping portions of at least two first-type fan-out lines intersect. The conductive layers include: a first conductive layer, a second conductive layer, and at least one third conductive layer. Overlapping portions of two first-type fan-out lines that intersect are respectively located in the first conductive layer and the second conductive layer.

### CROSS-REFERENCE TO RELATED APPLICATIONS

This application is a national phase entry under 35 USC 371 of International Patent Application No. PCT/CN2025/076559, filed on Feb. 8, 2025, which claims priority to Chinese Patent Application No. 202410324205.9, filed on Mar. 20, 2024, each are incorporated herein by reference in their entirety.

### TECHNICAL FIELD

The present disclosure relates to the field of display technologies, and in particular, to a display panel and a display apparatus.

### BACKGROUND

Organic light-emitting diode (OLED) display technology is a technology that utilizes a luminescent material to emit light driven by an electric current to realize display. OLED displays have the advantages of ultra-small weight, ultra-small thickness, high brightness, large viewing angle, low voltage, low power consumption, fast response, high definition, vibration resistance, bendable, low cost, simple process, using less raw materials, high luminous efficiency and wide temperature range.

### SUMMARY

In an aspect, a display panel is provided, having a display region and a fan-out region. The fan-out region is located on a side of the display region. The display panel includes a substrate and a plurality of conductive layers stacked on a side of the substrate. The plurality of conductive layers include: a plurality of data lines, a plurality of connection lines and a plurality of fan-out lines. The plurality of data lines are arranged at intervals in a first direction, and the plurality of data lines extend in a second direction, the second direction and the first direction intersecting. The plurality of data lines include a plurality of first data lines and a plurality of second data lines. The plurality of first data lines are located in at least one edge region of the display region, and the plurality of second data lines are located in a central region adjoining the edge region. A first end of a connection line is located in an edge region and is electrically connected to a first data line, and a second end of the connection line extends to a junction of the central region and the fan-out region. At least one connection line crosses at least one data line, and is insulated from the at least one data line that the at least one connection line crosses. The plurality of fan-out lines are located in the fan-out region. A single fan-out line is connected to a single connection line or a single second data line. The plurality of fan-out lines include a plurality of first-type fan-out lines. A first-type fan-out line includes an overlapping portion. In a thickness direction of the substrate, orthographic projections, on the substrate, of overlapping portions of at least two first-type fan-out lines intersect, so that an arrangement order of ends, proximate to the display region, of the at least two first-type fan-out lines in the first direction is different from an arrangement order of ends, away from the display region, of the at least two first-type fan-out lines in the first direction. The plurality of conductive layers include at least a first conductive layer, a second conductive layer, and at least one third conductive layer. The at least one third conductive layer is located between the first conductive layer and the second conductive layer, and overlapping portions of two first-type fan-out lines that intersect are respectively located in the first conductive layer and the second conductive layer.

In some embodiments, extending directions of two overlapping portions of the two first-type fan-out lines intersect.

In some embodiments, the first-type fan-out line further includes at least one transfer portion. In a same first-type fan-out line, an overlapping portion is located in the first conductive layer, and at least one transfer portion extends from any conductive layer in the thickness direction of the substrate to the first conductive layer and is connected to the overlapping portion.

In some embodiments, an extending direction of a part of the transfer portion located in the first conductive layer is different from an extending direction of the overlapping portion.

In some embodiments, the first-type fan-out line further includes: at least one connection portion. In a same first-type fan-out line, a connection portion and an overlapping portion are connected, and are arranged in a same layer.

In some embodiments, an extending direction of the connection portion and an extending direction of the overlapping portion are the same or approximately the same.

In some embodiments, an extending direction of the connection portion is different from an extending direction of the overlapping portion.

In some embodiments, the display panel further has a bending region and a chip on panel region that are sequentially away from the display region; the fan-out region includes a first fan-out region and a second fan-out region; the first fan-out region is located between the display region and the bending region; the second fan-out region is located between the bending region and the chip on panel region; and the overlapping portion is located in the second fan-out region.

In some embodiments, a width of the overlapping portion is greater than or equal to 1.0 μm.

In some embodiments, the display panel further includes: at least one shielding pattern. The shielding pattern is used to receive a constant voltage signal. The shielding pattern is located in the fan-out region, and is located in the third conductive layer. An overlapping region of orthographic projections of two overlapping portions on the substrate is located within an orthographic projection of a shielding pattern on the substrate.

In some embodiments, the at least one shielding pattern includes a plurality of shielding patterns, and at least two shielding patterns among the plurality of shielding patterns are located in a same third conductive layer and are connected to each other.

In some embodiments, the plurality of conductive layers include at least two source-drain conductive layers that are sequentially stacked. The at least one shielding pattern includes a plurality of shielding patterns, and the plurality of shielding patterns are located in any one or any two of the at least two source-drain conductive layers.

In some embodiments, the plurality of conductive layers further include: a light-blocking layer and at least two gate conductive layers that are sequentially stacked on a side of the at least two source-drain conductive layers proximate to the substrate. The first conductive layer is any one layer of the light-blocking layer and the at least two gate conductive layers.

In some embodiments, the plurality of conductive layers further include: at least two touch electrode layers that are sequentially stacked on a side of the at least two source-drain conductive layers away from the substrate. The second conductive layer is any one layer of the at least two source-drain conductive layers and the at least two touch electrode layers.

In another aspect, a display apparatus is provided, including the display panel as described in any one of the above embodiments.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely accompanying drawings of some embodiments of the present disclosure, and a person of ordinary skill in the art can obtain other drawings according to those drawings. In addition, the accompanying drawings to be described below may be regarded as schematic diagrams, and are not limitations on actual sizes of products involved in the embodiments of the present disclosure.

FIG. 1 is a structural diagram of a display apparatus, in accordance with some embodiments of the present disclosure;

FIG. 2 is a structural diagram of a display panel, in accordance with some embodiments of the present disclosure;

FIG. 3 is a structural diagram of a display substrate, in accordance with some embodiments of the present disclosure;

FIG. 4 is a structural diagram of a connection structure of a light-emitting device and a pixel driving circuit in a sub-pixel, in accordance with some embodiments of the present disclosure;

FIG. 5 is a structural diagram of another display substrate, in accordance with some embodiments of the present disclosure;

FIG. 6 is a structural diagram of another display panel, in accordance with some embodiments of the present disclosure;

FIG. 7 is a structural diagram of yet another display panel, in accordance with some embodiments of the present disclosure;

FIG. 8 is a partial structural diagram of a display panel, in accordance with some embodiments of the present disclosure;

FIG. 9 is a structural diagram of yet another display panel, in accordance with some embodiments of the present disclosure;

FIG. 10 is a partial structural diagram of another display panel, in accordance with some embodiments of the present disclosure;

FIG. 11 is a partial structural diagram of yet another display panel, in accordance with some embodiments of the present disclosure;

FIG. 12 is a partial structural diagram of yet another display panel, in accordance with some embodiments of the present disclosure;

FIG. 13 is a partial structural diagram of yet another display panel, in accordance with some embodiments of the present disclosure;

FIG. 14 is a partial structural diagram of yet another display panel, in accordance with some embodiments of the present disclosure;

FIG. 15 is a partial structural diagram of yet another display panel, in accordance with some embodiments of the present disclosure;

FIG. 16 is a sectional view of a structure in FIG. 15 taken along the line DD′;

FIG. 17 is a partial structural diagram of yet another display panel, in accordance with some embodiments of the present disclosure;

FIG. 18 is a partial structural diagram of yet another display panel, in accordance with some embodiments of the present disclosure;

FIG. 19 is a partial structural diagram of yet another display panel, in accordance with some embodiments of the present disclosure;

FIG. 20 is a partial structural diagram of yet another display panel, in accordance with some embodiments of the present disclosure;

FIG. 21 is a partial structural diagram of yet another display panel, in accordance with some embodiments of the present disclosure; and

FIG. 22 is a partial structural diagram of yet another display panel, in accordance with some embodiments of the present disclosure.

### DETAILED DESCRIPTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

Hereinafter, terms such as “first” and “second” are used for descriptive purposes only, and are not to be construed as indicating or implying the relative importance or implicitly indicating the number of indicated technical features. Thus, features defined with “first” and “second” may explicitly or implicitly include one or more of the features. In the description of the embodiments of the present disclosure, the terms “a plurality of”, “the plurality of” and “multiple” each mean two or more unless otherwise specified.

The phrase “A and/or B” includes the following three combinations: only A, only B, and a combination of A and B.

The term such as “about”, “substantially” or “approximately” as used herein includes a stated value and an average value within an acceptable range of deviation of a particular value. The acceptable range of deviation is determined by a person of ordinary skill in the art in view of measurement in question and errors associated with measurement of a particular quantity (i.e., limitations of a measurement system).

The term such as “perpendicular” or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system). For example, the term “perpendicular” includes absolute perpendicularity and approximate perpendicularity, and an acceptable range of deviation of the approximate perpendicularity may be, for example, a deviation within 5°; and the term “equal” includes absolute equality and approximate equality, and an acceptable range of deviation of the approximate equality may be that, for example, a difference between the two that are equal is less than or equal to 5% of either of the two.

It will be understood that, when a layer or element is referred to as being on another layer or substrate, it may be that the layer or element is directly on the another layer or substrate, or it may be that intermediate layer(s) exist between the layer or element and the another layer or substrate.

Exemplary embodiments are described herein with reference to sectional views and/or plan views that are schematic illustrations of idealized embodiments. In the drawings, thicknesses of layers and areas of regions are enlarged for clarity. Variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Thus, the regions shown in the accompanying drawings are schematic in nature, and their shapes are not intended to show actual shapes of the regions in a device, and are not intended to limit the scope of the exemplary embodiments.

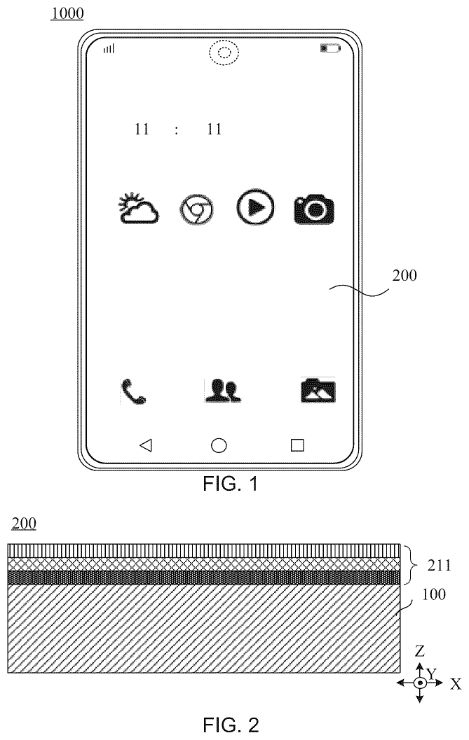

As shown in FIG. 1, some embodiments of the present disclosure provide a display apparatus 1000. The display apparatus 1000 may be any display apparatus 1000 that displays images whether in motion (e.g., videos) or stationary (e.g., static images), and whether textual or graphical. More specifically, it is expected that the display apparatus 1000 in the embodiments may be implemented in or associated with various electronic devices, which include (but are not limit to), for example, a mobile phone, a wireless device, a personal digital assistant (PDA), a hand-held or portable computer, a GPS receiver/navigator, a camera, an MP4 video player, a video camera, a game console, a watch, a clock, a calculator, a TV monitor, a flat panel display, a computer monitor, a car display (e.g., an odometer display), a navigator, a cockpit controller and/or display, a display in camera view (e.g., a display for a rear camera in a vehicle), an electronic photo, an electronic billboard or indicator, a projector, a building structure, a packaging and aesthetic structure (e.g., a display for an image of a piece of jewelry).

The display apparatus 1000 includes a display panel 200. In some examples, the display panel 200 is an organic light-emitting diode (OLED) display or a quantum dot light-emitting diode (QLED) display.

Based on this, the display apparatus 1000 may further include an under-screen camera and an under-screen fingerprint recognition sensor, so that the display apparatus can realize various functions such as photographing, video recording, and fingerprint recognition.

As shown in FIG. 2, the display panel 200 includes a display substrate 100. For example, as shown in FIG. 2, the display panel 200 may further include other functional film layers 211 (such as a touch functional layer, an anti-reflection layer, an anti-fingerprint layer, a hardening layer, and an encapsulation cover plate) located on a display side of the display substrate 100, so that the display panel 200 can realize different functions.

The embodiments of the present disclosure do not limit other functional film layers 211 of the display panel 200. The display structure 100 will be exemplarily described below.

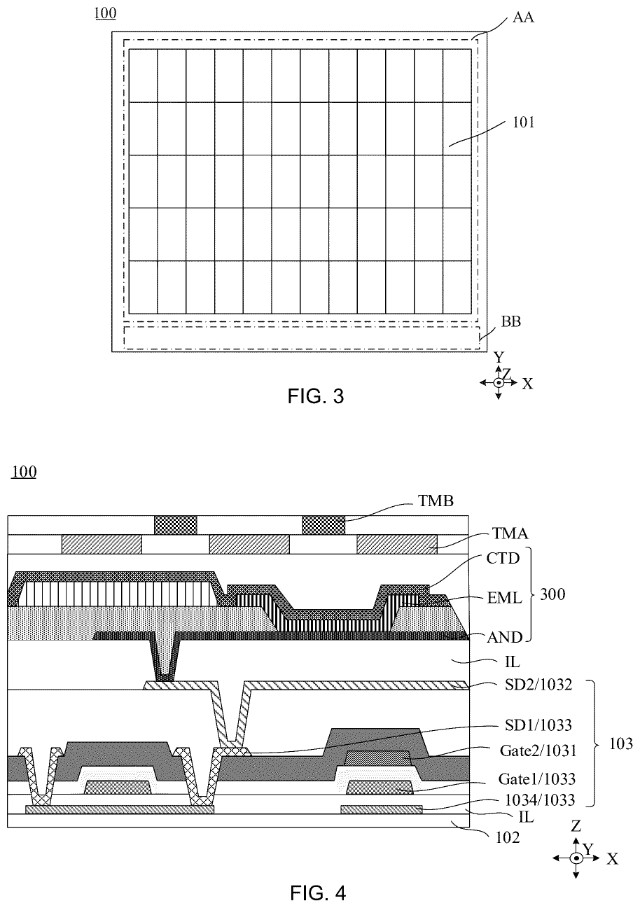

As shown in FIG. 3, the display substrate 100 includes a plurality of sub-pixels 101. The plurality of sub-pixels 101 are arranged in a plurality of columns in a first direction X, and are arranged in a plurality of rows in a second direction Y.

In some examples, the first direction X and the second direction Y intersect.

For example, the first direction X is perpendicular to the second direction Y. For example, the first direction X is a horizontal direction, and the second direction Y is a vertical direction.

It can be understood that the sub-pixel 101 is the smallest unit of the display substrate 100 for displaying images. Each sub-pixel 101 may display a single color such as red, green or blue. The display substrate 100 may include a plurality of red sub-pixels, a plurality of green sub-pixels and a plurality of blue sub-pixels. By adjusting brightness (grayscale) of sub-pixels 101 of different colors, red light, green light and blue light with different intensities will be obtained. At least two of red light, green light and blue light with different intensities are superimposed, and thus light of a plurality of colors may be displayed, thereby realizing full-color display of the display substrate 100.

It can be understood that, as shown in FIG. 3, the display substrate 100 has a display region AA and a fan-out region BB, and the fan-out region BB is located on a side of the display region AA. The fan-out region BB adjoins at least one edge of the display region AA. The display region AA is used to display image information, and the plurality of sub-pixels 101 are located in the display region AA of the display substrate 100.

It will be noted that, the fan-out region BB adjoining at least one edge of the display region AA means that at least one edge of the fan-out region BB proximate to the display region AA coincides with at least one edge of the display region AA proximate to the fan-out region BB. In the accompanying drawings of the present disclosure, considering FIG. 3 as an example, the edge of the fan-out region BB and the edge of the display region AA are separated from each other, which is only for convenience of showing the display region AA and the fan-out region BB, but is not limitations on the display region AA and the fan-out region BB.

In some examples, as shown in FIG. 3, the fan-out region BB is located on a side of the display region AA in the second direction Y.

In some examples, as shown in FIG. 3, the fan-out region BB adjoins a lower edge of the display region AA. That is, the fan-out region BB is located on a lower side of the display region AA in the second direction Y.

For example, in a case where the display panel 200 is used in a state of being perpendicular or approximately perpendicular to the ground, the fan-out region BB is closer to the ground than the display region AA.

In some examples, each sub-pixel 101 includes a light-emitting device 300 and a pixel driving circuit, and the pixel driving circuit is electrically connected to the light-emitting device 300 and used for driving the light-emitting device 300 to emit light.

In some examples, as shown in FIG. 4, the display panel 200 or the display substrate 100 includes a substrate 102 and a plurality of conductive layers 103. The plurality of conductive layers 103 are located on the same side of the substrate 102. The plurality of conductive layers 103 are stacked.

In some examples, the substrate 102 is made of a flexible material, so that the display substrate 100 is capable of being bent, and thus the display panel 200 can achieve functions of curved display, foldable display, or slidable display. In some other examples, the substrate 102 is made of a rigid material.

For example, a material of the substrate 102 may be any one of polyimide (PI), polycarbonate (PC), or polyvinyl chloride (PVC).

In some examples, an insulating layer IL (e.g., a gate insulating layer, a buffer layer, an interlayer dielectric layer, a passivation layer, an organic layer, etc.) may be provided between the plurality of conductive layers 103, and the insulating layer IL is used to electrically isolate two adjacent conductive layers 103.

In some other examples, the insulating layer IL between the plurality of conductive layers 103 does not include a passivation layer. In this way, a thickness of the display panel 200 may be reduced, which is conducive to realizing a light and thin design of the display panel 200.

For example, the pixel driving circuit is arranged in the plurality of conductive layers 103. In some examples, as shown in FIG. 4, the plurality of conductive layers 103 include: a light-blocking layer (not shown in the figure), an active film layer 1034, at least one gate conductive layer Gate (such as a first gate conductive layer Gate1, a second gate conductive layer Gate2, and a third gate conductive layer (which is not shown in the figure and may be located between the second gate conductive layer Gate2 and a first source-drain conductive layer SD1)), and at least one source-drain conductive layer SD (such as a first source-drain conductive layer SD1, a second source-drain conductive layer SD2, and a third source-drain conductive layer (which is not shown in the figure and may be located between the second source-drain conductive layer SD2 and an anode layer AND)), which are sequentially away from the substrate 102.

It will be understood that in the case where the display panel 200 includes a touch functional layer, the plurality of conductive layers 103 in the display panel 200 further include: at least one touch electrode layer disposed on a side of the at least one source-drain conductive layer SD away from the substrate 102. Here, the at least one touch electrode layer constitutes the touch functional layer.

For example, as shown in FIG. 4, the plurality of conductive layers 103 include: a first touch electrode layer TMA and a second touch electrode layer TMB disposed on the side of the at least one source-drain conductive layer SD away from the substrate 102. In the case where the display panel includes a light-emitting device, the first touch electrode layer TMA and the second touch electrode layer TMB are located on a surface of the light-emitting device away from the substrate 102. For example, the first touch electrode layer TMA includes a plurality of first touch electrodes, and the second touch electrode layer TMB includes a plurality of second touch electrodes,

The pixel driving circuit includes a plurality of thin film transistors (TFTs) and at least one capacitor. For example, the active film layer 1034 and the first gate conductive layer Gate1 may be used to form some thin film transistors (e.g., one, two or more thin film transistors) among the plurality of thin film transistors, and the active film layer 1034 and the second gate conductive layer Gate2 may be used to form some other thin film transistors (e.g., one, two or more thin film transistors) among the plurality of thin film transistors. The first gate conductive layer Gate1 and the second gate conductive layer Gate2 may be used to form the at least one capacitor.

It will be noted that the number of active film layers 1034 is not limited here. For example, some embodiments of the present disclosure may only include one active film layer 1034, and a material of the active film layer 1031 may include metal oxide or low temperature polysilicon. Alternatively, some embodiments of the present disclosure may include two active film layers 1034, a material of one active film layer 1034 includes metal oxide, and a material of the other active film layer includes low temperature polysilicon.

It can be seen from the above embodiments, the display substrate 100 further includes the light-emitting device 300, and the pixel driving circuit is electrically connected to the light-emitting device 300. With continued reference to FIG. 4, the light-emitting device 300 will be exemplarity described below.

In some examples, the light-emitting device 300 is located on a side of the plurality of conductive layers 103 away from the substrate 102. It can be understood that, in the case where the plurality of conductive layers 103 include the at least one touch electrode layer, the light-emitting device 300 is located between the at least one source-drain conductive layer SD and the at least one touch electrode layer.

For example, the light-emitting device 300 includes an anode layer AND, a portion of a light-emitting layer EML and a cathode layer CTD that are sequentially arranged in a direction away from the substrate 102.

In some examples, the light-emitting layer EML includes a plurality of effective light-emitting portions arranged at intervals. It can be understood that the effective light-emitting portion is used to emit light. For example, the effective light-emitting portion includes an electroluminescence material. It can be understood that electroluminescence refers to a phenomenon in which an organic semiconductor material, driven by an electric field (an electric field provided by anode and cathode layers), undergo carrier injection, transport, and electron-hole combination to generate excitons, and in turn radiate and recombine to cause light emission.

It can be understood that a part of the plurality of effective light-emitting portions is used to emit red light, another part of the plurality of effective light-emitting portions is used to emit green light, and yet another part of the plurality of effective light-emitting portions is used to emit blue light. For example, different electroluminescent materials may be selected, so that the effective light-emitting portions can emit light of different colors. It can be understood that the number of effective light-emitting portions that emit red light, the number of effective light-emitting portions that emit green light, and the number of effective light-emitting portions that emit blue light may be the same or different.

For example, the effective light-emitting portions that emit red light, the effective light-emitting portions that emit green light, and the effective light-emitting portions that emit blue light may be mixed and arranged in an array. In this way, by controlling luminous intensities of different effective light-emitting portions, red light, green light, and blue light of different intensities will be obtained. By mixing red light, green light and blue light of different intensities, the display substrate 100 and the display panel 200 may display a colorful image.

It can be understood that the pixel driving circuit drives the light-emitting layer EML to emit light. In some examples, a pixel driving circuit is electrically connected to an effective light-emitting portion through the anode layer AND, so that each pixel driving circuit can provide a driving current to a respective effective light-emitting portion through the anode layer AND. That is, the plurality of effective light-emitting portions emit light independently, thereby reducing mutual interference between the plurality of effective light-emitting portions, and improving the display effect of the display substrate 100 and the display panel 200. It can be understood that by adjusting the driving current provided by the pixel driving circuit to the effective light-emitting portion, the light-emitting brightness of the effective light-emitting portion will be adjusted.

In some examples, a material of the anode layer AND includes a metal material, such as copper or silver. A material of the cathode layer CTD includes a light-transmitting material, such as light-transmitting indium tin oxide (ITO) or light-transmitting indium zinc oxide (IZO), so that light emitted by the effective light-emitting portion can exit through the cathode layer CTD. In this case, the display substrate 100 is a top emission display substrate.

In some other examples, the material of the anode layer AND includes a transparent material, such as ITO or IZO, and the material of the cathode layer CTD includes a metal material, such as copper or silver, so that the light emitted by the effective light-emitting portion can exit through the anode layer AND. In this case, the display substrate 100 is a bottom emission display substrate.

In yet some other examples, the materials of the anode layer AND and the cathode layer CTD each include a transparent material, such as ITO or IZO, so that the light emitted by the effective light-emitting portion can exit through the anode layer AND and the cathode layer CTD. In this case, the display substrate 100 is a double-sided light-emitting display substrate.

In some examples, in consideration of work function, the material of the anode layer AND includes ITO or a stack of ITO-Ag-ITO, so that the anode layer AND can provide more holes. The material of the cathode layer CTD includes MgAg, so that the cathode layer CTD can provide more electrons. The cathode layer CTD has a very small thickness and may transmit light, so that the display substrate 100 can achieve top emission.

In some examples, in a direction from the anode layer AND to the effective light-emitting portion, at least one of a hole injection layer (HIL), a hole transport layer (HTL) and an electron blocking layer (EBL) is provided between the anode layer AND and the effective light-emitting portion. In a direction from the cathode layer CTD to the effective light-emitting portion, at least one of an electron injection layer (EIL), an electron transport layer (ETL) and a hole blocking layer (HBL) is provided between the cathode layer CTD and the effective light-emitting portion. In this way, the luminous efficiency of the effective light-emitting portion is improved.

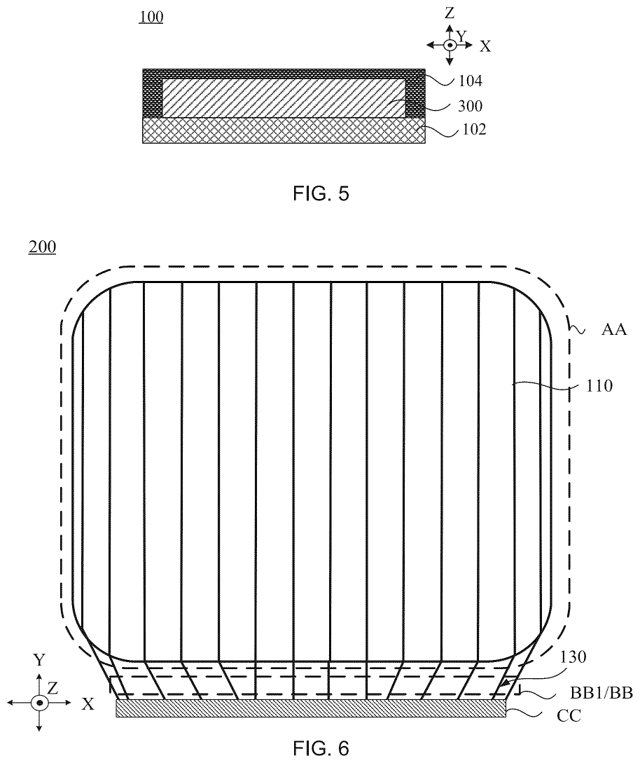

FIG. 5 is a structural diagram of a display substrate, in accordance with some other embodiments.

In some examples, as shown in FIG. 5, the display substrate 100 further includes an encapsulation layer 104. The encapsulation layer 104 is located on a side of the light-emitting device 300 away from the substrate 102, and covers the light-emitting device 300 to wrap the light-emitting device 300, so as to prevent moisture and oxygen in an external environment from entering the light-emitting device 300, thereby protecting the light-emitting device 300.

FIG. 6 is a structural diagram of a display panel, in accordance with yet some other embodiments. As shown in FIG. 6, the plurality of conductive layers 103 include the pixel driving circuit, and further include a plurality of data lines 110 and a plurality of fan-out lines 130. It can be understood that, the plurality of data lines 110 are located in the display region AA and are electrically connected to a plurality of pixel driving circuits, and are used to transmit driving signals to the pixel driving circuits, so that the pixel driving circuits can drive light-emitting devices 300 to emit light, to realize display of different grayscales.

In some examples, as shown in FIG. 6, the plurality of data lines 110 are arranged at intervals in the first direction X, and the plurality of data lines 110 extend in the second direction Y. The second direction Y and the first direction X intersect, and the first direction X and the second direction Y may be parallel to the substrate 102.

In some examples, the first direction X is perpendicular or approximately perpendicular to the second direction Y. For example, as shown in FIG. 6, the first direction X is a horizontal direction, and the second direction Y is a vertical direction.

It can be seen from the above that, as shown in FIG. 3, the plurality of sub-pixels 101 are arranged in a plurality of columns in the first direction X, and are arranged in a plurality of rows in the second direction Y. That is, pixel driving circuits in the plurality of sub-pixels 101 are arranged in an array with a plurality of rows and a plurality of columns in the first direction X and the second direction Y. As shown in FIG. 6, the plurality of data lines 110 extend in the second direction Y. In this way, a single data line 110 is electrically connected to pixel driving circuits in a single column of sub-pixels 101 arranged in the second direction Y, so as to provide a data voltage to the pixel driving circuits in the single column of sub-pixels 101.

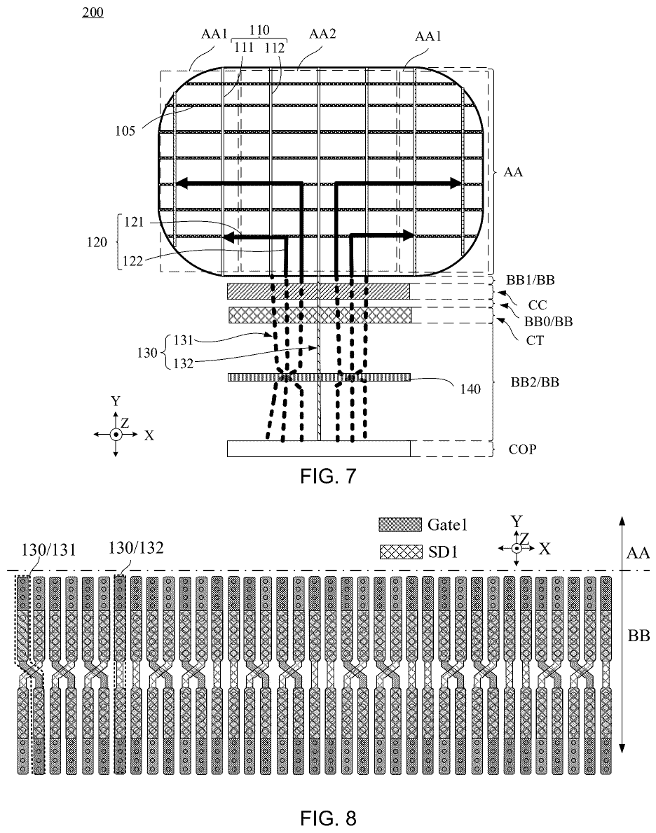

In some examples, as shown in FIG. 7, the plurality of data lines 110 include a plurality of first data lines 111 and a plurality of second data lines 112. The plurality of first data lines 111 are located in at least one edge region AA1 of the display region AA, and the plurality of second data lines 112 are located in a central region AA2 adjoining the edge region AA1.

For example, as shown in FIG. 7, there are two edge regions AA1, and the two edge regions AA1 are located on two edges of the display panel 200 in the first direction X; and the central region AA2 is located between the two edge regions A11 in the first direction X.

For example, the central region AA2 may be a region of the display region AA that is directly opposite or substantially directly opposite to the fan-out region BB in the second direction Y. The edge region AA1 may be a region of the display region AA that is not directly opposite to the fan-out region BB in the second direction Y.

For example, in the first direction X, the two edge regions AA1 of the display region AA have the same or approximately the same widths. In some examples, as shown in FIG. 7, the display region AA includes rounded corner(s). That is, two adjacent edges of the display region AA are connected by an arc or an approximately arc-shaped curve. The rounded corner is located in the edge region AA1 of the display region AA.

For example, a width of the edge region AA1 in the first direction X may be greater than or equal to a width of the rounded corner in the first direction X.

For example, the number of the first data lines 111 and the number of the second data lines 112 may be the same or different. Moreover, the numbers of first data lines 111 located in the two edge regions AA1 may be the same or different.

It will be noted that, in the embodiments of the present disclosure, the first data lines 111 and the second data lines 112 are only used to distinguish the data lines 110 located in the edge regions AA1 and the central region AA2, and do not further limit other aspects of the data lines 110.

For example, the plurality of first data lines 111 and the plurality of second data lines 112 are located in the same conductive layer 103. For example, the plurality of first data lines 111 and the plurality of second data lines 112 are located in the first source-drain conductive layer SD1. For another example, the plurality of first data lines 111 and the plurality of second data lines 112 are located in the second source-drain conductive layer SD2. For yet another example, the plurality of first data lines 111 and the plurality of second data lines 112 may be located in other conductive layer 103 (e.g., the third source-drain conductive layer) other than the first source-drain conductive layer SD1 and the second source-drain conductive layer SD2.

As shown in FIG. 7, the plurality of conductive layers 103 further include a plurality of connection lines 120. A first end of a connection line 120 (i.e., an arrow end in FIG. 7) is located in an edge region AA1 of the display region AA, and is electrically connected to a first data line 111. A second end of the connection line 120 (i.e., an end opposite to the arrow end in FIG. 7) extends to a junction of the central region AA2 of the display region AA and the fan-out region BB.

For example, as shown in FIG. 7, a second end of any connection line 120 among the plurality of connection lines 120 extends to the central region AA2 of the display region AA.

It can be seen from the above that, an edge of the display region AA proximate to the fan-out region BB may coincide with an edge of the fan-out region BB proximate to the display region AA. The second end of the connection line 120 extends to the junction of the central region AA2 and the fan-out region BB. It can be understood that, the second end of the connection line 120 may be located on a boundary line between the central region AA2 and the fan-out region BB. Alternatively, the second end of the connection line 120 and the boundary line may have therebetween a small gap, e.g., a gap of several microns. In this case, the second end of the connection line 120 may be located on a side of the boundary line proximate to the display region AA, or may be located on a side of the boundary line proximate to the fan-out region BB.

As shown in FIG. 7, at least one connection line 120 crosses at least one data line 110 (for example, a first data line 111 and/or a second data line 112), and is insulated from the data line(s) 110 that the at least one connection line 120 crosses.

It can be understood that, since the plurality of data lines 110 are arranged at intervals in the first direction X, second ends of some connection lines 120 need to cross at least one data line 110 when extending to the junction of the central region AA2 and the fan-out region BB. For example, at least one connection line 120 may cross the first data line 111 and the second data line 112. For another example, at least one connection line 120 may cross only the first data line 111 (not shown in the figure). For yet another example, at least one connection line 120 may cross only the second data line 112 (not shown in the figure).

In addition, the display panel 200 may further include a connection line 120 that does not cross any data line 110.

It can be understood that the connection line 120 crossing at least one data line 110 means that an orthographic projection of the connection line 120 on the substrate 102 intersects with an orthographic projection of the at least one data line 110 on the substrate 102.

In some examples, the connection line 120 and the data line 110 are located in different conductive layers 103, so that the connection line 120 may be insulated from the data line(s) 110 that the connection line 120 crosses.

For example, the data lines 110 are located in the first source-drain conductive layer SD1, and the connection lines 120 are located in the second source-drain conductive layer SD2. Alternatively, the data lines 110 are located in the second source-drain conductive layer SD2, and the connection lines 120 are located in the third source-drain conductive layer.

For example, in the case where the connection line 120 and the data line 110 are located in different conductive layers 103, the first end of the connection line 120 may be connected to the first data line 111 through via hole(s). It can be understood that the via hole(s) penetrate through an insulating layer between two adjacent conductive layers 103 in a direction perpendicular or approximately perpendicular to the substrate 102, so that different conductive layers 103 can be electrically connected, and conductive wires (e.g., the connection line 120 and the data line 110) located in different conductive layers 103 can be electrically connected. For example, when two conductive layers 103 are not adjacent, conductive lines located in different conductive layers 130 may be electrically connected through a plurality of via holes. Therefore, the connection line 120 can be insulated from the data line(s) 110 that the connection line 120 crosses.

In some other examples, the connection line 120 includes a main body portion and a jumper portion. The main body portion and the jumper portion may be electrically connected through via hole(s). The main body portion may be located in the same conductive layer 103 as the data line 110. That is, the main body portion and the data line 110 are arranged in the same layer. For example, the main body portion and the data line 110 are located in the first source-drain conductive layer among the plurality of conductive layers 103. The jumper portion and the data line 110 may be located in two different conductive layers 103, and the jumper portion and the data line 110 are arranged in different layers. For example, the data line 110 is located in the first source-drain conductive layer, and the jumper portion is located in the second source-drain conductive layer among the plurality of conductive layers 103. An insulating layer is provided between the first source-drain conductive layer and the second source-drain conductive layer, so that the jumper portion can cross at least one data line 110 and be insulated from the data line(s) 110 that the jumper portion crosses.

As shown in FIG. 7, a second end of at least one connection line 120 is located between two adjacent second data lines 112. Therefore, a second end of one connection line 120 may be disposed between two adjacent second data lines 112; alternatively, second ends of two or more connection lines 120 may be disposed between two adjacent second data lines 112.

It can be understood that, as shown in FIG. 7, there may be a second end of one connection line 120 between any group of two adjacent second data lines 112; alternatively, there may be second ends of two or more connection lines 120 between any group of two adjacent second data lines 112; alternatively, there may not be a second end of a connection line 120 between any group of two adjacent second data lines 112. The number of second ends of connection lines 120 arranged between each group of different groups of two adjacent second data lines 112 may be the same or different.

As shown in FIG. 7, the second end of the connection line 120 is arranged between two adjacent second data lines 112, so that the second end of the connection line 120 can pass through a gap between the two adjacent second data lines 112 to extend to the junction of the central region AA2 and the fan-out region BB.

It can be understood that the number of the connection lines 120 and the number of the first data lines 111 may be the same or different. In some examples, the number of the connection lines 120 is the same as the number of the first data lines 111. The plurality of connection lines 120 and the plurality of first data lines 111 are connected in one-to-one correspondence. In some other examples, the number of connection lines 120 is less than the number of first data lines 111; in this case, all connection lines 120 may be connected to a part of the first data lines 111 in one-to-one correspondence, and another part of the first data lines 111 may not be connected to a connection line 120.

In some examples, as shown in FIG. 7, the connection line 120 includes a first connection sub-line 121 and a second connection sub-line 122. An end of the first connection sub-line 121 is located in the edge region AA1, and is electrically connected to the first data line 111. Another end of the first connection sub-line 121 extends to the central region AA2. An end of the second connection sub-line 122 is electrically connected to the first connection sub-line 121 (for example, the end of the second connection sub-line 122 is connected to an end of the first connection sub-line 121, or the end of the second connection sub-line 122 is connected to a middle part of the first connection sub-line 121), and another end of the second connection sub-line 122 extends to the junction of the central region AA2 and the fan-out region BB. For example, the first connection sub-line 121 extends in the first direction X, the second connection sub-line 122 extends in the second direction Y, and the first connection sub-line 121 and the second connection sub-line 122 are perpendicular or approximately perpendicular to each other.

In the case where the connection line 120 includes a main body portion and a jumper portion, as shown in FIG. 7, in some examples, for the first connection sub-line 121 and the second connection sub-line 122 included in the connection line 120, the second connection sub-line 122 may be used as a main body portion, and the main body portion and the plurality of data lines 110 are located in the same conductive layer 103; and the first connection sub-line 121 is a jumper portion, and the jumper portion and the plurality of data lines 110 are located in two different conductive layers 103. The first connection sub-line 121 can cross at least one data line 110, and is insulated from the data line(s) 110 that the first connection sub-line 121 crosses. In addition, in some other examples, the second connection sub-line 122 may be used as a main body portion, and the first connection sub-line 121 includes both a main body portion and a jumper portion, and the jumper portion is used to cross the data line(s) 110.

In some examples, the jumper portion is farther away from the substrate 102 relative to the plurality of data lines 110. In this way, it is possible to reduce parasitic capacitance created between the jumper portion and a gate conductive layer Gate (e.g., the first gate conductive layer Gate1, the second gate conductive layer Gate2 and the third gate conductive layer) and improve the reliability of signal transmission.

For example, the above fan-out manner for data lines of adding the connection lines 120 may be referred to as a Fanout In AA (FIAA) or Fanout In Panel (FIP).

In some examples, as shown in FIG. 7, in the case where the number of the connection lines 120 is the same as the number of the first data lines 110, the first data lines 111 and the connection lines 120 are connected in one-to-one correspondence. This arrangement manner may be referred to as All FIAA.

In some other examples, a part of the first data lines 111 may be connected to the connection lines 120 in one-to-one correspondence, and another part of the first data lines 111 may not be connected to the connection lines 120. For example, similar to the second data lines 112, the another part of the first data lines 111 may be directly led out through fan-out lines (e.g., second-type fan-out lines 132 mentioned below). In this way, it is conducive to reducing spacing between the plurality of data lines 110, increasing the pixel density of the display region AA, and enabling the display panel 200 to realize high pixels per inch (PPI). This arrangement manner may be referred to as Part FIAA.

As shown in FIG. 7, the plurality of conductive layers 103 further include a plurality of fan-out lines 130. The plurality of fan-out lines 130 are located in the fan-out region BB. A fan-out line 130 is connected to a connection line 120 or a second data line 112.

For example, an end of a fan-out line 130 is connected to a corresponding first data line 111 via a connection line 120; or, an end of a fan-out line 130 is connected to a second data line 112. In this way, the plurality of fan-out lines 130 are electrically connected to the plurality of data lines 110 in one-to-one correspondence. Another ends of the plurality of fan-out lines 130 are electrically connected to a driver chip (integrated circuit (IC)). The driver IC inputs data signals to all pixel driving circuits through the plurality of fan-out lines 130 and the plurality of data lines 110.

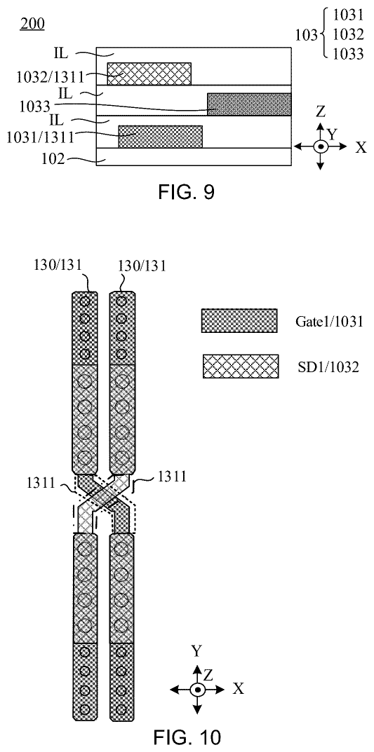

As shown in FIG. 8, the plurality of fan-out lines 130 further include a plurality of first-type fan-out lines 131. As shown in FIGS. 9 and 10, the first-type fan-out line 131 includes an overlapping portion 1311. In a thickness direction of the substrate 102, orthographic projections of overlapping portions 1311 of at least two first-type fan-out lines 131 on the substrate 102 intersect. Therefore, an arrangement order of ends, proximate to the display region AA, of the at least two first-type fan-out lines 131 in the first direction X is different from an arrangement order of ends, away from the display region AA, of the at least two first-type fan-out lines 131 in the first direction X.

It can be understood that, an orthographic projection, on the substrate 102, of a remaining portion of a first-type fan-out line 131 other than the overlapping portion 1311 does not overlap with orthographic projections, on the substrate 102, of other fan-out lines 130 (here, other fan-out lines 130 may be other first-type fan-out lines 131 other than the above-mentioned first-type fan-out line 131, and second-type fan-out lines 132 mentioned below).

For example, as shown in FIG. 10, a shape of orthographic projections of the overlapping portions 1311 of two first-type fan-out lines 131 on the substrate 102 may be or may approximately be a cross shape. Thus, in the first direction X, an arrangement order of portions of the two first-type fan-out lines 131 on a side of the overlapping portions 1311 and an arrangement order of portions of the two first-type fan-out lines 131 on another side of the overlapping portions 1311 are exchanged, that is, the order is changed. Therefore, by using the overlapping portions 1311 of the first-type fan-out lines 131, an order of the plurality of first-type fan-out lines 131 may be changed. An arrangement order of ends, away from the display region AA, of the plurality of fan-out lines 130 in the first direction X is the same as an arrangement order of a plurality of data lines 110 that are connected to the plurality of fan-out lines 130 in the first direction X. Therefore, an arrangement order of output terminals of the driver IC in the first direction X, the arrangement order of the ends, away from the display region AA, of the plurality of fan-out lines 130 in the first direction X, and an arrangement order of the plurality of data lines 110 in the first direction X are the same. The output terminals of the driver IC sequentially provide driving signals to the plurality of data lines 110, so that the driver IC sequentially drive a plurality of columns of sub-pixels 101 to emit light, without re-developing the driver IC. Thus, the cost of the display substrate 100 is reduced.

In an implementation, the overlapping portions 1311 of the two first-type fan-out lines 131 are respectively located in the first source-drain conductive layer SD1 and the second source-drain conductive layer SD2. The first source-drain conductive layer SD1 and the second source-drain conductive layer SD2 are adjacent conductive layers, so that a distance between the two overlapping portions 1311 in the thickness direction of the substrate 102 is relatively small. Therefore, in a case where data signals received by the two first-type fan-out lines 131 are different, the data signals transmitted by the two first-type fan-out lines 131 are prone to crosstalk with each other, and the two overlapping portions 1311 are prone to create a parasitic capacitor. Thus, the load of the first-type fan-out line 131 is large, leading to large loss of the data signal received by the data line 110 connected to the first-type fan-out line 131, and poor accuracy and stability of the data signal. As a result, the image display quality of the display panel 200 and the display apparatus 1000 is affected.

In light of this, in the embodiments of the present disclosure, as shown in FIGS. 9 and 10, the plurality of conductive layers 103 include at least a first conductive layer 1031, a second conductive layer 1032, and at least one third conductive layer 1033. The at least one third conductive layer 1033 is located between the first conductive layer 1031 and the second conductive layer 1032.

The relative position between the first conductive layer 1031 and the second conductive layer 1032 may be set according to actual needs, which will not be limited in the embodiments of the present disclosure.

For example, the second conductive layer 1032 is closer to the substrate 102 than the first conductive layer 1031.

For another example, as shown in FIG. 9, the first conductive layer 1031 is closer to the substrate 102 than the second conductive layer 1032.

For example, in the case where the first conductive layer 1031 is closer to the substrate 102 than the second conductive layer 1032, for example, among a plurality of third conductive layers 1033, one third conductive layer 1033A is located between the first conductive layer 1031 and the second conductive layer 1032, other two third conductive layers 1033B and 1033C are located on a side of the first conductive layer 1031 proximate to the substrate 102, and another third conductive layer 1033D is located on a side of the second conductive layer 1032 away from the substrate 102. For another example, among the plurality of third conductive layers 1033, at least two third conductive layers 1033A and 1033B are located between the first conductive layer 1031 and the second conductive layer 1032, and remaining third conductive layer(s) 1033 are located on the side of the first conductive layer 1031 proximate to the substrate 102. For yet another example, among the plurality of third conductive layers 1033, at least two third conductive layers 1033A and 1033B are located between the first conductive layer 1031 and the second conductive layer 1032, and remaining third conductive layer(s) 1033 are located on the side of the second conductive layer 1032 away from the substrate 102.

As shown in FIG. 10, the overlapping portions 1311 of the two first-type fan-out lines 131 intersecting are located in the first conductive layer 1031 and the second conductive layer 1032, respectively.

Based on the above description, the at least one third conductive layer 1033 is located between the first conductive layer 1031 and the second conductive layer 1032. Therefore, the distance between the two intersecting overlapping portions 1311 in the thickness direction of the substrate 102 (i.e., the third direction Z in FIG. 10) is relatively large. Crosstalk is not likely to occur between the data signals transmitted by the two overlapping portions 1311, and a capacitance value of the parasitic capacitor between the two overlapping portions 1311 may be reduced to a certain extent, thereby reducing the load of the first-type fan-out line 131 including the overlapping portion 1311, improving the accuracy and stability of the signal transmitted by the first-type fan-out line 131, and improving the image display quality of the display panel 200 and the display apparatus 1000.

Moreover, in this way, the present disclosure only improves the existing conductive layer(s) 103 of the display panel 200, and does not add a new conductive layer. Therefore, there is no need to add a new mask and preparation process, etc., and the image display quality of the display panel 200 and the display apparatus 1000 is improved without increasing the preparation cost of the display panel 200.

In addition, in the process of forming two overlapping portions, an etching process is generally used, so as to etch conductive layers to form conductive wires (the conductive wires may be the fan-out lines, etc.), and etch the insulating layer to form via holes for realizing connections of the conductive wires in two conductive layers (for example, conductive patterns in different layers). Since the distance between the two intersecting overlapping portions 1311 in the above examples of the present disclosure is relatively large, it may be possible to reduce or even avoid the probability of short-circuiting the two overlapping portions 1311 due to over-etching of an insulating layer under a film layer where the overlapping portion 1311 close to the substrate 102 is located, and to avoid over-etch connection caused by the large distance between the two overlapping portions 1311. Thus, it is conducive to improving the preparation yield of the display panel 200.

It can be understood that the above examples are described by taking an example in which the orthographic projections of the overlapping portions 1311 of the two first-type fan-out lines 131 on the substrate 102 intersect. In the case where orthographic projections of overlapping portions 1311 of three first-type fan-out lines 131 on the substrate 102 intersect, the three overlapping portions 1311 are respectively located in different conductive layers 103. Referring to FIG. 12, FIG. 12 shows that the three overlapping portions 1311 are respectively located in the first gate conductive layer Gate1, the first source-drain conductive layer SD1, and the second touch electrode layer TMB.

In some examples, as shown in FIG. 10, the overlapping portion 1311 has a certain length. For example, the overlapping portion 1311 may be in a shape of a long strip in a top view. Extending directions of the two overlapping portions 1311 of the two first-type fan-out lines 131 intersect.

For example, among the two overlapping portions 1311, an extending direction of one overlapping portion 1311 may be the first direction X, and an extending direction of another overlapping portion 1311 may be the second direction Y. For another example, among the two overlapping portions 1311, an extending direction of one overlapping portion 1311 may be the first direction X, and an extending direction of another overlapping portion 1311 may be the third direction, where the third direction intersects each of the first direction X and the second direction Y. For yet another example, as shown in FIG. 10, among the two overlapping portions 1311, an extending direction of one overlapping portion 1311 may be a fifth direction, and an extending direction of another overlapping portion 1311 may be a fourth direction, where the fifth direction intersects each of the first direction X and the second direction Y, and the fourth direction intersects each of the first direction X, the second direction Y, and the third direction.

In this case, through the overlapping portions 1311, the plurality of first-type fan-out lines 131 to which the overlapping portions 1311 belong may be reordered. Therefore, the arrangement order of the ends, away from the display region AA, of the plurality of fan-out lines 130 in the first direction X is the same as the arrangement order of the plurality of data lines 110 that are connected to the plurality of fan-out lines 130 in the first direction X. As a result, the cost of the display panel 200 is reduced.

It can be understood that the structure of the first-type fan-out line 131 varies, which may be set according to actual needs and will not be limited in the present disclosure.

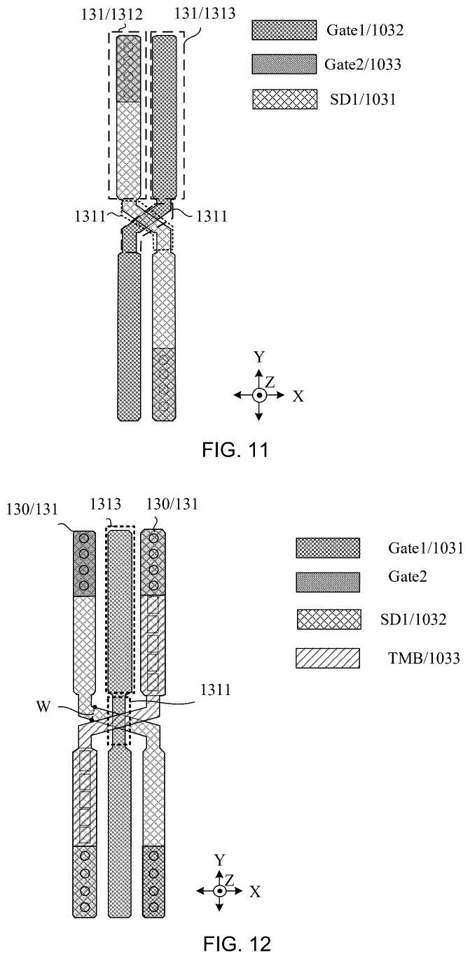

In some examples, as shown in FIG. 11, the first-type fan-out line 131 further includes at least one transfer portion 1312. In the same first-type fan-out line 131, the overlapping portion 1311 is located in the first conductive layer 1031, and the transfer portion 1312 extends from any conductive layer to the first conductive layer 1031 in the thickness direction of the substrate 102 and is connected to the overlapping portion 1311.

For example, the transfer portion 1312 extends to the first conductive layer 1031 through via hole(s) in an insulating layer between the any conductive layer and the first conductive layer 1031.

For example, a part of the transfer portion 1312 is located in the second conductive layer 1032, and another part of the transfer portion 1312 extends from the second conductive layer 1032 to the first conductive layer 1031 through at least one third conductive layer 1033, to be connected to the overlapping portion 1311.

For another example, as shown in FIG. 11, a part of the transfer portion 1312 is located in the third conductive layer 1033, and another part of the transfer portion 1312 extends from the third conductive layer 1033 to the first conductive layer 1031, to be connected to the overlapping portion 1311.

In this way, the connection between the transfer portion 1312 and the overlapping portion 1311 in the first-type fan-out line 131 may be ensured, so that the first-type fan-out line 131 is switched from any conductive layer 103 to the first conductive layer 1031.

For example, as shown in FIG. 11, in the same first-type fan-out line 131, an extending direction of the part of the transfer portion 1312 located in the first conductive layer 1031 is different from the extending direction of the overlapping portion 1311. Therefore, in the top view, the first-type fan-out line 131 is in a shape of a broken line or approximately in a shape of a broken line.

For example, the extending direction of the part of the transfer portion 1312 located in the first conductive layer 1031 is the second direction Y, and the extending direction of the overlapping portion 1311 is the fourth direction.

In this way, it is conducive to realizing order change of the first-type fan-out lines 131.

For example, in the same first-type fan-out line 131, the extending direction of the part of the transfer portion 1312 located in the first conductive layer 1031 may be the same as the extending direction of the overlapping portion 1311. Therefore, in the top view, the first-type fan-out line 131 is in a shape of a straight line or approximately in a shape of a straight line.

In some other examples, as shown in FIG. 12, the first-type fan-out line 131 further includes at least one connection portion 1313. In the same first-type fan-out line 131, the connection portion 1313 and the overlapping portion 1311 are connected and are arranged in the same layer.

For example, the overlapping portion 1311 and the connection portion 1313 connected thereto are both located in the first conductive layer 1031 or the second conductive layer 1032.

Therefore, the overlapping portion 1311 and the connection portion 1313 may be in the same layer and made of the same material. The connection portion 1313 and the overlapping portion 1311 may be formed in one manufacturing process, which is conducive to simplifying the manufacturing process of the first-type fan-out line 131 and the display panel 200.

It can be understood that an extending direction of the connection portion 1313 and the extending direction of the overlapping portion 1311 may be set according to actual needs, which will not be limited in the embodiments of the present disclosure.

For example, as shown in FIG. 12, the extending direction of the connection portion 1313 and the extending direction of the overlapping portion 1311 may be the same or approximately the same. Therefore, in the top view, the first-type fan-out line 131 is in a shape of a straight line or approximately in a shape of a straight line.

For another example, as shown in FIG. 11, the extending direction of the connection portion 1313 is different from the extending direction of the overlapping portion 1311. Therefore, in the top view, the first-type fan-out line 131 is in a shape of a broken line or approximately in a shape of a broken line.

In some examples, as shown in FIG. 12, a width W of the overlapping portion 1311 is greater than or equal to 1.0 μm.

Here, the width W of the overlapping portion 1311 refers to a dimension of the overlapping portion 1311 in a direction perpendicular to the extending direction of the overlapping portion 1311.

For example, the width W of the overlapping portion 1311 is greater than or equal to 1.5 μm.

For example, the width W of the overlapping portion 1311 may be 1.0 μm, 1.5 μm, 1.7 μm, 2.0 μm, or 2.5 μm.

In this way, it may ensure that the width of the overlapping portion 1311 is relatively large, avoid defects such as breakage and short circuit in the overlapping portion 1311, and prevent the transmission of the signal from being affected.

In some embodiments, as shown in FIG. 7, the fan-out lines 130 further include second-type fan-out lines 132.

For example, the second-type fan-out lines 132 are connected to the second data lines 112.

Orthographic projections of the second-type fan-out lines 132 on the substrate do not overlap with orthographic projections of other fan-out lines 130 on the substrate. For example, the second-type fan-out lines 132 do not require order change, and are directly connected to the driver IC.

For example, in the first direction X, the plurality of first-type fan-out lines 131 and a plurality of second-type fan-out lines 132 are alternately arranged. For example, three first-type fan-out lines 131 may be a first group, and one second-type fan-out line 132 may be a second group, and the first group and the second group are alternately arranged (that is, an insertion order is 3-in-1). Of course, the embodiments of the present disclosure are not limited to this. For example, 2-in-1, 4-in-1, 4-in-2, etc. modes may also be used. On this basis, portions, proximate to the display region, of adjacent fan-out lines 130 (e.g., adjacent first-type fan-out line 131 and second-type fan-out line 132, or adjacent first-type fan-out lines 131, or two adjacent second-type fan-out lines 132) may be located in different gate conductive layers Gate. For example, a portion of one fan-out line 130 proximate to the display region is located in the first gate conductive layer Gate1 (as can be seen from the above, the entire fan-out line may be located in the same conductive layer or in different conductive layers; the portion of the first-type fan-out line proximate to the display region may be the transfer portion 1312 or the connection portion 1313 of the first-type fan-out line proximate to the display region), and a portion of another fan-out line proximate to the display region is located in the second gate conductive layer Gate2. In this way, it is conducive to reducing signal crosstalk between adjacent fan-out lines.

In some examples, as shown in FIG. 7, the display panel 200 further has a bending region CC and a chip on panel (COP) region that are sequentially away from the display region AA. The COP region is used for mounting the driver IC. The fan-out region BB includes a first fan-out region BB1 and a second fan-out region BB2. The first fan-out region BB1 is located between the display region AA and the bending region CC, and the second fan-out region BB2 is located between the bending region CC and the COP region.

The fan-out lines 130 extend from the first fan-out region BB1 to the second fan-out region BB2 through the bending region CC, and the overlapping portions 1311 are located in the second fan-out region BB2. Thus, ends of the fan-out lines 130 proximate to the driver IC has completed the order change, and an arrangement order of the ends of the fan-out lines 130 proximate to the driver IC is the same as the arrangement order of the data lines 110. The driver IC may output data signals to all data lines 110 according to the arrangement order of the data lines 110 in the first direction X.

In some examples, as shown in FIG. 7, the display panel 200 further has a cell test (CT) region. The CT region is used for testing the display panel 200. In this case, the second fan-out region BB2 may be located between the CT region and the COP region. It will be noted that, a distance between the CT region and the bending region CC may be zero (that is, an intermediate fan-out region BBO shown in FIG. 7 may not exist), or may not be zero (that is, an intermediate fan-out region BBO shown in FIG. 7 may exist).

In addition, in the case where the intermediate fan-out region BBO exists, the intermediate fan-out region BBO may be part of the second fan-out region BB2 (not shown in figure), or may not be part of the second fan-out region BB2 (as shown in FIG. 7).

In some examples, the display substrate 100 further has an inner lead bonding (ILB) region (not shown in figure) and a flexible printed circuit on panel (FOP) region (not shown in figure). The ILB region and the FOP region are sequentially located on a side of the COP region away from the second fan-out region BB2. In some examples, some pins of the driver IC may be electrically connected to pins in the FOP region through wires in the ILB region, and the pins in the FOP region may be used to connect to an external flexible printed circuit.

In some examples, as shown in FIG. 7, the display substrate 100 may further include a plurality of scan control signal lines 105. The plurality of scan control signal lines 105 are arranged at intervals in the second direction Y and extend in the first direction X. In this way, a scan control signal line 105 can be electrically connected to pixel driving circuits in a row of sub-pixels 101 arranged in the first direction X, so as to control operating states of the pixel driving circuits in the row of sub-pixels 101.

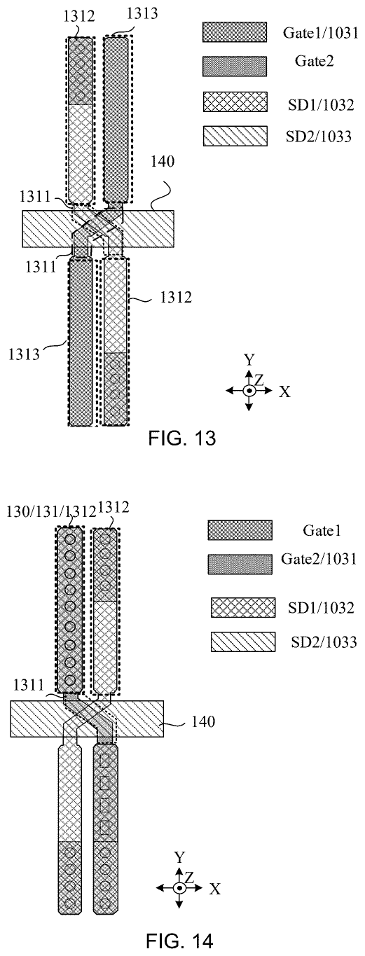

In some examples, as shown in FIGS. 7 and 13, the display panel 200 further includes at least one shielding pattern 140. The shielding pattern 140 is located in the fan-out region BB, and is located in the third conductive layer 1033.

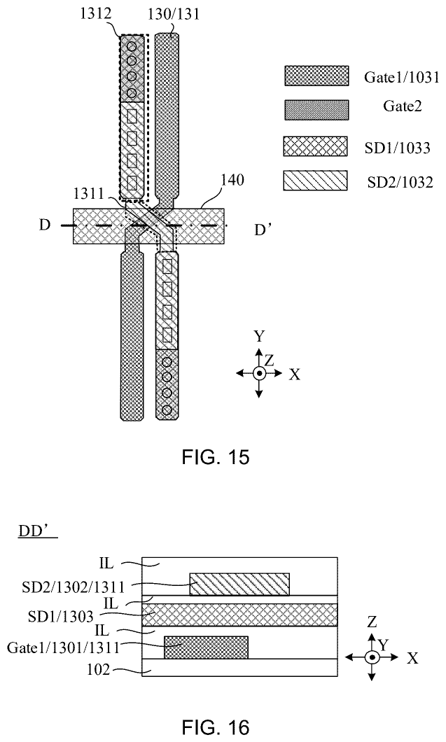

The shielding pattern 140 and the overlapping portion 1311 are arranged in different layers. For example, in the thickness direction of the substrate 102, the shielding pattern 140 may be located in the third conductive layer 1033 above the two intersecting overlapping portions 1311 (see FIGS. 13 and 14), or located in the third conductive layer 1033 below the two intersecting overlapping portions 1311, or located in the third conductive layer 1033 between the two intersecting overlapping portions 1311 (see FIG. 15).

The shielding pattern 140 receives a constant voltage signal. For example, the shielding pattern 140 may receive a first voltage signal (VDD) transmitted by a first voltage signal line, or receive a common voltage signal (VSS) transmitted by a common voltage signal line.

As shown in FIG. 13, an overlapping region of orthographic projections of the two overlapping portions 1311 on the substrate 102 is located within an orthographic projection of the shielding pattern 140 on the substrate 102.

In this way, the shielding pattern 140 may be used to protect at least one overlapping portion 1311, thereby reducing interference of a signal transmitted by a conductive structure (such as a signal line, a capacitor, etc.) located on a side of the shielding pattern 140 away from the overlapping portion 1311 on a signal of the overlapping portion 1311, and improving the stability of the signal transmitted by the first-type fan-out line 131. For example, in the case where the shielding pattern 140 is located in the third conductive layer 1033 between the two overlapping portions 1311 (see FIGS. 15 and 16), the shielding pattern 140 may shield signals transmitted by the two overlapping portions 1311, thereby reducing crosstalk and interference between the signals transmitted by the two overlapping portions 1311, and improving the accuracy of the signal transmitted by the first-type fan-out line 131.

In some examples, as shown in FIG. 7, a plurality of shielding patterns 140 are located in the same third conductive layer 1033 and are connected to each other.

For example, among the plurality of shielding patterns 140, one shielding pattern 140 is arranged corresponding to two intersecting overlapping portions 1311.

Therefore, it may be possible to reduce the difficulty of manufacturing the shielding patterns 140 and the display panel 200, and to improve the shielding effect of the shielding patterns 140.

As can be seen from the above, the plurality of conductive layers 103 include: at least two source-drain conductive layers SD that are sequentially stacked. For example, the plurality of shielding patterns 140 are located in any one or any two of the at least two source-drain conductive layers.

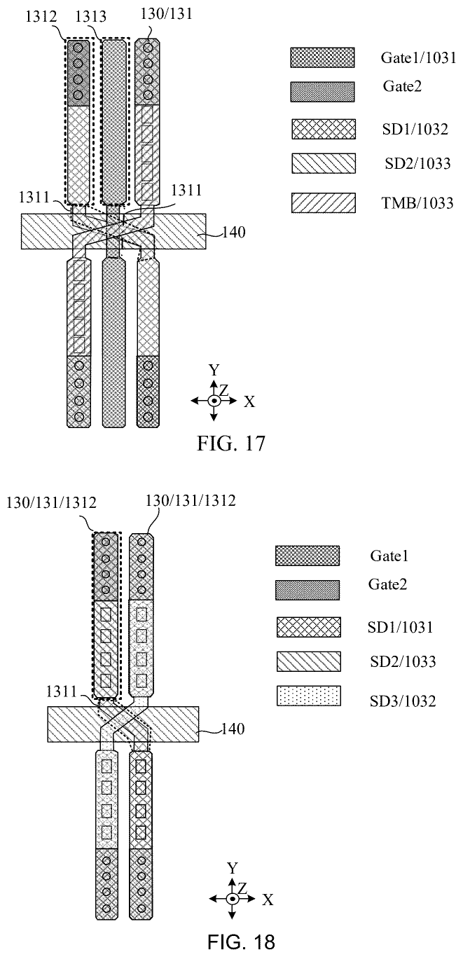

For example, the plurality of conductive layers 103 include: a first source-drain conductive layer SD1 and a second source-drain conductive layer SD2. The plurality of shielding patterns 140 are located in the first source-drain conductive layer SD1 (see FIGS. 15 and 17) or the second source-drain conductive layer SD2 (see FIG. 14).

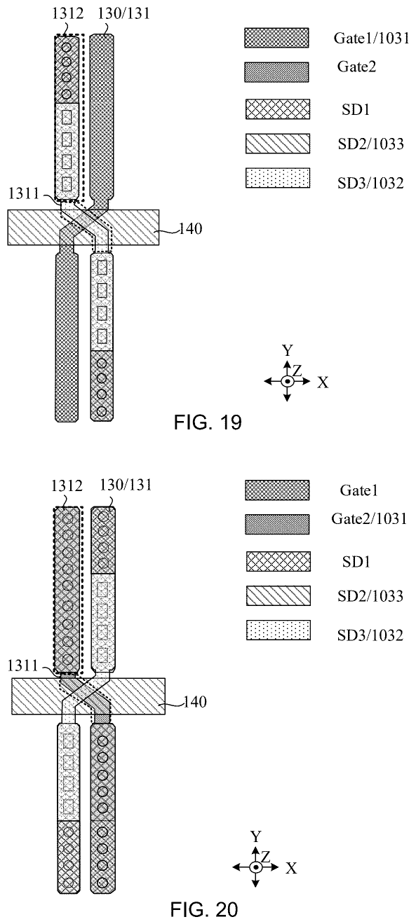

For example, the plurality of conductive layers 103 include: a first source-drain conductive layer SD1, a second source-drain conductive layer SD2 and a third source-drain conductive layer SD3. For example, the plurality of shielding patterns 140 may be located in the first source-drain conductive layer SD1, or may be located in the second source-drain conductive layer SD2 (see FIGS. 19, 20 and 21), or may be located in the third source-drain conductive layer SD3 (see FIG. 22). For another example, among the plurality of shielding patterns 140, a certain number of shielding patterns 140 are located in the first source-drain conductive layer SD1, and remaining shielding patterns 140 are located in the second source-drain conductive layer SD2. For yet another example, among the plurality of shielding patterns 140, a certain number of shielding patterns 140 are located in the second source-drain conductive layer SD2, and a certain number of shielding patterns 140 are located in the third source-drain conductive layer SD3.

As can be seen from the above, the plurality of conductive layers 103 further include: a light-blocking layer and at least two gate conductive layers Gate, which are sequentially stacked on a side of the at least two source-drain conductive layers proximate to the substrate 102. In some examples, the first conductive layer 1031 is any one of the light-blocking layer and the at least two gate conductive layers Gate.

For example, the plurality of conductive layers 103 include: a light-blocking layer, a first gate conductive layer Gate1 and a second gate conductive layer Gate2. The first conductive layer 1031 is the light-blocking layer, the first gate conductive layer Gate1, or the second gate conductive layer Gate2. Therefore, the overlapping portions 1311 of the first-type fan-out lines 131 are located in the light-blocking layer, the first gate conductive layer Gate1 (see FIGS. 11, 12, 15 and 17), or the second gate conductive layer Gate2 (see FIG. 14).

For example, the plurality of conductive layers 103 include: a light-blocking layer, a first gate conductive layer Gate1, a second gate conductive layer Gate2, and a third gate conductive layer Gate3. The first conductive layer 1031 is the light-blocking layer, the first gate conductive layer Gate1, the second gate conductive layer Gate2, or the third gate conductive layer Gate3. Therefore, the overlapping portions 1311 of the first-type fan-out lines 131 are located in the light-blocking layer, the first gate conductive layer Gate1 (see FIGS. 15 and 17), the second gate conductive layer Gate2 (see FIG. 14), or the third gate conductive layer Gate3.

As can be seen from the above, the plurality of conductive layers 103 further include: at least two touch electrode layers sequentially stacked on a side of the at least two source-drain conductive layers SD away from the substrate 102. In some examples, the second conductive layer 1032 is any one layer of the at least two source-drain conductive layers SD and the at least two touch electrode layers.

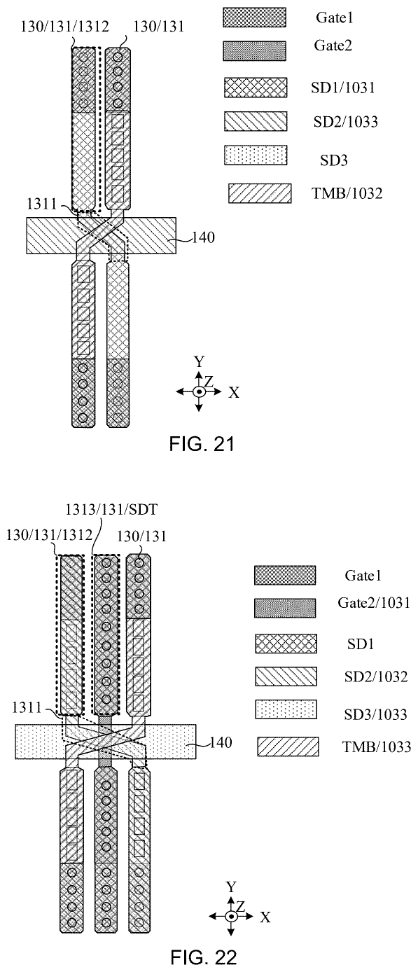

For example, the plurality of conductive layers 103 further include: a first source-drain conductive layer SD1, a second source-drain conductive layer SD2, a first touch electrode layer TMA, and a second touch electrode layer TMB. The second conductive layer 1032 is the first source-drain conductive layer SD1, the second source-drain conductive layer SD2, the first touch electrode layer, or the second touch electrode layer. Therefore, the overlapping portions 1311 of the first-type fan-out lines 131 are located in the first source-drain conductive layer SD1, the second source-drain conductive layer SD2, the first touch electrode layer, or the second touch electrode layer TMB (see FIGS. 21 and 22).

In this way, the intersecting overlapping portions 1311 of at least two first-type fan-out lines 131 may be located in two different conductive layers 103, and the distance between the two conductive layers 103 is large, thereby reducing the crosstalk between data signals transmitted by the at least two overlapping portions 1311, reducing capacitance values of parasitic capacitors created by a plurality of overlapping portions 1311, reducing loads of the overlapping portions 1311, and improving the stability of the data signals received by the data lines. In addition, by providing the shielding pattern 140, the crosstalk between the data signal transmitted by the overlapping portion 1311 and other conductive layers may be further reduced, thereby effectively improving the stability of the data signal, and in turn improving the image quality of the display panel 200 and the display apparatus 1000.

The structure of the first-type fan-out line 131 and the shielding pattern 140 in FIGS. 13 to 22 are briefly introduced below.

For example, in FIG. 13, among the two first-type fan-out lines 131, one first-type fan-out line 131 includes two transfer portions 1312 and an overlapping portion 1311, where one transfer portion 1312 extends from the second gate conductive layer Gate2 to the first source-drain conductive layer SD1 through via hole(s) in the insulating layer between the second gate conductive layer Gate2 and the first source-drain conductive layer SD1, and is connected to an end of the overlapping portion 1311 located in the first source-drain conductive layer SD1; another end of the overlapping portion 1311 is connected to another transfer portion 1312; and the another transfer portion 1312 extends from the first source-drain conductive layer SD1 to the first gate conductive layer Gate1 through via hole(s) between the first source-drain conductive layer SD1 and the first gate conductive layer Gate1. Another first-type fan-out line 131 includes two connection portions 1313 and an overlapping portion 1311, which are arranged in the same layer and are all located in the first gate conductive layer Gate1. The shielding pattern 140 is located in the second source-drain conductive layer SD2.

For example, in FIG. 14, two first-type fan-out lines 131 each include two transfer portions 1312 and an overlapping portion 1311. The two overlapping portions 1311 are respectively located in the second gate conductive layer Gate2 and the first source-drain conductive layer SD1. A transfer portion 1312 extends from the first source-drain conductive layer SD1 to the second gate conductive layer Gate2 through via hole(s), and is connected to the overlapping portion 1311 in the second gate conductive layer Gate2. Another transfer portion 1312 extends from the first gate conductive layer Gate1 to the first source-drain conductive layer SD1 through via hole(s), and is connected to the overlapping portion 1311 located in the first source-drain conductive layer SD1. The shielding pattern 140 is located in the second source-drain conductive layer SD2.

For example, in FIG. 15, a first-type fan-out line 131 includes two transfer portions 1312 and an overlapping portion 1311. The transfer portion 1312 extends from the second gate conductive layer Gate2 through via hole(s) to the first source-drain conductive layer SD1 and the second source-drain conductive layer SD2 in sequence, and is connected to the overlapping portion 1311 located in the second source-drain conductive layer SD2. Another first-type fan-out line 131 is located in the first gate conductive layer Gate1, and its overlapping portion 1311 is located in the first gate conductive layer Gate1. The shielding pattern 140 is located in the first source-drain conductive layer SD1.

For example, FIG. 16 is a sectional view of a structure in FIG. 15 taken along the line DD′. In the third direction Z, the shielding pattern 140 is located between the two overlapping portions 1311.

For example, in FIG. 17, a transfer portion 1312 of a first-type fan-out line 131 extends from the second gate conductive layer Gate2 through via hole(s) to the first source-drain conductive layer SD1, and is connected to an overlapping portion 1311 located in the first source-drain conductive layer SD1. A transfer portion 1312 of another first-type fan-out line 131 extends from the second gate conductive layer Gate2 through via hole(s) to the first source-drain conductive layer SD1 and the second touch electrode layer TMB in sequence, and is connected to an overlapping portion 1311 located in the second touch electrode layer TMB. A connection portion 1313 and an overlapping portion 1311 of yet another first-type fan-out line 131 (the middle first-type fan-out line 131) are both located in the first gate conductive layer Gate1. The shielding pattern 140 is located in the second source-drain conductive layer SD2.

For example, in FIG. 18, a transfer portion 1312 of a first-type fan-out line 131 extends from the second gate conductive layer Gate2 through via hole(s) to the first source-drain conductive layer SD1, and is connected to an overlapping portion 1311 located in the first source-drain conductive layer SD1. A transfer portion 1312 of another first-type fan-out line 131 extends from the first gate conductive layer Gate1 through via hole(s) to the first source-drain conductive layer SD1 and the third source-drain conductive layer SD3 in sequence, and is connected to an overlapping portion 1311 located in the third source-drain conductive layer SD3. The shielding pattern 140 is located in the second source-drain conductive layer SD2. In the third direction Z, the shielding pattern 140 is located between the two overlapping portions 1311.

For example, in FIG. 19, a transfer portion 1312 of a first-type fan-out line 131 extends from the second gate conductive layer Gate2 through via hole(s) to the first source-drain conductive layer SD1 and the third source-drain conductive layer SD3 in sequence, and is connected to an overlapping portion 1311 located in the third source-drain conductive layer SD3. A connection portion 1313 and an overlapping portion 1311 of another first-type fan-out line 131 are both located in the first gate conductive layer Gate1. The shielding pattern 140 is located in the second source-drain conductive layer SD2. In the third direction Z, the shielding pattern 140 is located between the two overlapping portions 1311. In this example, the arrangement position of the shielding pattern 140 varies. For example, the plurality of shielding patterns 140 may be arranged in the first source-drain conductive layer SD1 and/or in the second source-drain conductive layer SD2.

For example, in FIG. 20, a transfer portion 1312 of a first-type fan-out line 131 extends from the first gate conductive layer Gate1 through via hole(s) to the first source-drain conductive layer SD1 and the second gate conductive layer Gate2 in sequence, and is connected to an overlapping portion 1311 located in the second gate conductive layer Gate2. A transfer portion 1312 of another first-type fan-out line 131 extends from the second gate conductive layer Gate2 through via hole(s) to the first source-drain conductive layer SD1 and the third source-drain conductive layer SD3 in sequence, and is connected to an overlapping portion 1311 located in the third source-drain conductive layer SD3. The shielding pattern 140 is located in the second source-drain conductive layer SD2. In this example, the arrangement position of the shielding pattern 140 varies. For example, the plurality of shielding patterns 140 may be arranged in the first source-drain conductive layer SD1 and/or in the second source-drain conductive layer SD2.

For example, in FIG. 21, a transfer portion 1312 of a first-type fan-out line 131 extends from the first gate conductive layer Gate1 through via hole(s) to the first source-drain conductive layer SD1, and is connected to an overlapping portion 1311 located in the first source-drain conductive layer SD1. A transfer portion 1312 of another first-type fan-out line 131 extends from the second gate conductive layer Gate2 through via hole(s) to the first source-drain conductive layer SD1 and the second touch electrode layer TMB in sequence, and is connected to an overlapping portion 1311 located in the second touch electrode layer TMB. The shielding pattern 140 is located in the second source-drain conductive layer SD2. In the third direction Z, the shielding pattern 140 is located between the two overlapping portions 1311. In this example, the arrangement position of the shielding pattern 140 varies. For example, the plurality of shielding patterns 140 may be arranged in the first source-drain conductive layer SD1 and/or in the second source-drain conductive layer SD2.

For example, in FIG. 22, a transfer portion 1312 of a first-type fan-out line 131 extends from the first gate conductive layer Gate1 through via hole(s) to the first source-drain conductive layer SD1 and the second source-drain conductive layer SD2 in sequence, and is connected to an overlapping portion 1311 located in the second source-drain conductive layer SD2. A transfer portion 1312 of another first-type fan-out line 131 extends from the first gate conductive layer Gate1 through via hole(s) to the first source-drain conductive layer SD1 and the second touch electrode layer TMB, and is connected to an overlapping portion 1311 located in the second touch electrode layer TMB. A connection portion 1313 of yet another first-type fan-out line 131 (the middle first-type fan-out line 131) is located in the second gate conductive layer Gate2 (a first source-drain conductive pattern SDT above the connection portion 1313 is provided to reduce a difference in film thickness between the yet another first-type fan-out line 131 and other fan-out lines), and is connected to an overlapping portion 1311 located in the second gate conductive layer Gate2. The shielding pattern 140 is located in the third source-drain conductive layer SD3. In this example, the arrangement position of the shielding pattern 140 varies. For example, the plurality of shielding patterns 140 may be located in the first source-drain conductive layer SD1 and/or in the third source-drain conductive layer SD3. The shielding patterns 140 located in the first source-drain conductive layer SD1 may shield and protect the overlapping portions 1311 located in the second gate conductive layer Gate2 and the overlapping portions 1311 located in the second source-drain conductive layer SD2.

It can be understood that the structures of the first-type fan-out lines 131 and the shielding patterns 140 provided in the embodiments of the present disclosure are not limited to the structures shown in FIGS. 13 to 22.

The foregoing descriptions are merely specific implementations of the present disclosure, but the protection scope of the present disclosure is not limited thereto. Any changes or replacements that a person skilled in the art could conceive of within the technical scope of the present disclosure shall be included in the protection scope of the present disclosure. Therefore, the protection scope of the present disclosure should be determined by the protection scope of the claims.

What is claimed is:

1. A display panel, having a display region and a fan-out region, the fan-out region being located on a side of the display region;
the display panel comprising: a substrate and a plurality of conductive layers stacked on a side of the substrate; wherein
the plurality of conductive layers include: a plurality of data lines, a plurality of connection lines and a plurality of fan-out lines;
the plurality of data lines are arranged at intervals in a first direction and extend in a second direction, the second direction and the first direction intersecting; the plurality of data lines include a plurality of first data lines and a plurality of second data lines, the plurality of first data lines are located in at least one edge region of the display region, and the plurality of second data lines are located in a central region adjoining the edge region;
a first end of a connection line is located in an edge region and is electrically connected to a first data line, and a second end of the connection line extends to a junction of the central region and the fan-out region; at least one connection line crosses at least one data line, and is insulated from the at least one data line that the at least one connection line crosses;
the plurality of fan-out lines are located in the fan-out region; a single fan-out line is connected to a single connection line or a single second data line;
the plurality of fan-out lines include a plurality of first-type fan-out lines; a first-type fan-out line includes an overlapping portion; in a thickness direction of the substrate, orthographic projections, on the substrate, of overlapping portions of at least two first-type fan-out lines intersect, so that an arrangement order of ends, proximate to the display region, of the at least two first-type fan-out lines in the first direction is different from an arrangement order of ends, away from the display region, of the at least two first-type fan-out lines in the first direction;
wherein the plurality of conductive layers include: a first conductive layer, a second conductive layer, and at least one third conductive layer; the at least one third conductive layer is located between the first conductive layer and the second conductive layer; overlapping portions of two first-type fan-out lines that intersect are respectively located in the first conductive layer and the second conductive layer.

2. The display panel according to claim 1, wherein extending directions of two overlapping portions of the two first-type fan-out lines intersect.

3. The display panel according to claim 1, wherein the first-type fan-out line further includes at least one transfer portion; in a same first-type fan-out line, an overlapping portion is located in the first conductive layer, and at least one transfer portion extends from any conductive layer in the thickness direction of the substrate to the first conductive layer and is connected to the overlapping portion.

4. The display panel according to claim 3, wherein an extending direction of a part of the transfer portion located in the first conductive layer is different from an extending direction of the overlapping portion.

5. The display panel according to claim 1, wherein the first-type fan-out line further includes: at least one connection portion; in a same first-type fan-out line, a connection portion and an overlapping portion are connected, and are arranged in a same layer.

6. The display panel according to claim 5, wherein an extending direction of the connection portion and an extending direction of the overlapping portion are the same or approximately the same.

7. The display panel according to claim 5, wherein an extending direction of the connection portion is different from an extending direction of the overlapping portion.

8. The display panel according to claim 1, wherein the display panel further has a bending region and a chip on panel region that are sequentially away from the display region; the fan-out region includes a first fan-out region and a second fan-out region; the first fan-out region is located between the display region and the bending region; the second fan-out region is located between the bending region and the chip on panel region;
the overlapping portion is located in the second fan-out region.

9. The display panel according to claim 1, wherein a width of the overlapping portion is greater than or equal to 1.0 μm.

10. The display panel according to claim 1, further comprising at least one shielding pattern, wherein the shielding pattern is used to receive a constant voltage signal;
the shielding pattern is located in the fan-out region, and is located in the third conductive layer; an overlapping region of orthographic projections of two overlapping portions on the substrate is located within an orthographic projection of a shielding pattern on the substrate.

11. The display panel according to claim 10, wherein the at least one shielding pattern includes a plurality of shielding patterns, and the plurality of shielding patterns are located in a same third conductive layer and are connected to each other.

12. The display panel according to claim 10, wherein the plurality of conductive layers include at least two source-drain conductive layers that are sequentially stacked;
the at least one shielding pattern includes a plurality of shielding patterns, and the plurality of shielding patterns are located in any one or any two of the at least two source-drain conductive layers.

13. The display panel according to claim 12, wherein the plurality of conductive layers further include: a light-blocking layer and at least two gate conductive layers that are sequentially stacked on a side of the at least two source-drain conductive layers proximate to the substrate;
wherein the first conductive layer is any one layer of the light-blocking layer and the at least two gate conductive layers.

14. The display panel according to claim 12, wherein the plurality of conductive layers further include: at least two touch electrode layers that are sequentially stacked on a side of the at least two source-drain conductive layers away from the substrate;
wherein the second conductive layer is any one layer of the at least two source-drain conductive layers and the at least two touch electrode layers.

15. A display apparatus, comprising the display panel according to claim 1.

16. The display panel according to claim 3, further comprising at least one shielding pattern, wherein the shielding pattern is used to receive a constant voltage signal;
the shielding pattern is located in the fan-out region, and is located in the third conductive layer; an overlapping region of orthographic projections of two overlapping portions on the substrate is located within an orthographic projection of a shielding pattern on the substrate.

17. The display panel according to claim 5, further comprising at least one shielding pattern, wherein the shielding pattern is used to receive a constant voltage signal;
the shielding pattern is located in the fan-out region, and is located in the third conductive layer; an overlapping region of orthographic projections of two overlapping portions on the substrate is located within an orthographic projection of a shielding pattern on the substrate.

18. The display apparatus according to claim 15, wherein in the display panel, the first-type fan-out line further includes at least one transfer portion; in a same first-type fan-out line, an overlapping portion is located in the first conductive layer, and at least one transfer portion extends from any conductive layer in the thickness direction of the substrate to the first conductive layer and is connected to the overlapping portion.

19. The display apparatus according to claim 15, wherein in the display panel, the first-type fan-out line further includes: at least one connection portion; in a same first-type fan-out line, a connection portion and an overlapping portion are connected, and are arranged in a same layer.

20. The display apparatus according to claim 15, wherein the display panel further has a bending region and a chip on panel region that are sequentially away from the display region; the fan-out region includes a first fan-out region and a second fan-out region; the first fan-out region is located between the display region and the bending region; the second fan-out region is located between the bending region and the chip on panel region;
the overlapping portion is located in the second fan-out region.
